(19) United States
(12) Patent Application Publication
(10) Pub. No.: US 2014/0008705 A1
(43) Pub. Date: Jan. 9, 2014

(54) SEMICONDUCTOR DEVICE

(71) Applicant: SAMSUNG ELECTRONICS CO., LTD., Suwon-si (KR)

(72) Inventors: Joon- Young Choi, Suwon-si (KR); Kyung-Ho Lee, Suwon-si (KR); Sang-Jun Choi, Seoul (KR); Tae-Hyoung Koo, Hwaseong-si (KR); Sam-Jong Choi, Suwon-si (KR)

(73) Assignee: SAMSUNG ELECTRONICS CO., LTD., Suwon-si (KR)

(21) Appl. No.: 13/835,669

(22) Filed: Mar. 15, 2013

(30) Foreign Application Priority Data
Jul. 4, 2012 (KR) 10-2012-0073038

(51) Int. Cl. H01L 29/78; H01L 29/04

(52) U.S. Cl. CPC H01L 29/7827; H01L 29/045
USPC 257/255; 257/628

(57) ABSTRACT

A semiconductor device includes field regions formed in a substrate, and n-type impurity regions disposed between the field regions. At least one of the side surfaces of the field regions has a {100}, {310}, or {311} plane.

### CROSS-REFERENCE TO RELATED APPLICATION

This application claims priority under 35 U.S.C. §119 to Korean Patent Application No. 10-2012-0073038 filed on Jul. 4, 2012, the disclosure of which is hereby incorporated by reference in its entirety.

### BACKGROUND

1. Field

Embodiments of the inventive concept relate to a semiconductor wafer, a semiconductor device, and methods of fabricating the wafer and device.

2. Description of Related Art

Semiconductor devices having various field regions have been proposed.

### SUMMARY

Embodiments of the inventive concept provide a semiconductor wafer.

Other embodiments of the inventive concept provide an image sensor or a semiconductor device or a method of fabricating an image sensor or a semiconductor device.

Aspects of the inventive concept should not be limited by the above description, and other unmentioned aspects will be clearly understood by one of ordinary skill in the art from example embodiments described herein.

In accordance with an aspect of the inventive concept, a semiconductor device includes field regions formed in a substrate, and n-type impurity regions disposed between the field regions. At least one side surface of the field regions has a {100}, {310}, or {311} plane.

In particular embodiments, the substrate includes an epitaxial-growth layer; and a surface of the epitaxial-growth layer can have a {100} plane. The field regions can include a shallow field region and a deep field region, the deep field region extending deeper into the substrate than the shallow field region extends, and a side surface of the deep field region can have a {100}, {310}, or {311} plane. The shallow field region can be vertically aligned with the deep field region and can have a greater horizontal width than the deep field region.

In additional embodiments, each of the n-type impurity regions can horizontally overlap the deep field region. Each of the n-type impurity regions can also have (a) an upper boundary having a depth greater than a depth of a bottom end of the shallow field region and (b) a lower boundary having a depth smaller than a depth of a bottom end of the deep field region. Additionally, a side impurity region can be interposed between the field regions and the n-type impurity region, and the side impurity region can include at least one p-type impurity.

In further embodiments, a p-type impurity region formed in the substrate between the n-type impurity region and a surface of the substrate. The device can further include a transistor formed on the substrate, wherein the transistor is configured to overlap with the p-type impurity region, and a diffusion region formed in the substrate and aligned with a side surface of the transistor. The transistor can include a gate trench recessed into the substrate, a gate insulating layer conformally formed on an inner wall of the gate trench, and a gate electrode filling the gate trench. The transistor can also include a vertical channel that is oriented in a <100> or <110> orientation. The transistor can also include a channel having a width direction that forms an angle of about 15° to about 75° with the side surfaces of the field regions. Further still, the p-type impurity region can abut the field regions.

In accordance with another aspect of the inventive concept, a semiconductor device includes an epitaxial-growth layer having a surface with a {100} or {110} plane, where at least two field regions are formed in the epitaxial-growth layer. Each of the field regions has a side surface with a {100}, {110}, {310}, or {311} plane. A photodiode (PD) is formed between the field regions, and the photodiode includes an n-type impurity region formed in the epitaxial-growth layer and a p-type impurity region configured to abut the surface of the epitaxial-growth layer. A transistor is formed in the p-type impurity region and has a vertical channel oriented in a <100> or <110> orientation and a diffusion region formed in the p-type impurity region and aligned with one side surface of the transistor. The lengthwise direction of the vertical channel of the transistor forms an angle of about 15° to about 75° with the side surface of the field region.

In embodiments of this aspect of the inventive concept, the field regions can include a shallow field region and a deep field region, wherein the deep field region extends deeper into the epitaxial-growth layer than the shallow field region extends. Additionally, a side surface of the deep field region can have a {100}, {310}, or {311} plane. Further still, the p-type impurity region can be formed between the n-type impurity region and a surface of the epitaxial-growth layer. Moreover, the n-type impurity region can have (a) an upper boundary having a depth greater than a depth of a bottom end of the shallow field region and (b) a lower boundary having a depth smaller than a depth of a bottom end of the deep field region.

In accordance with another aspect of the inventive concept, a semiconductor device can include a substrate having a side surface at least one of a {310}, {311}, {100}, or {110} plane, the side surface being orthogonal to a top surface of the substrate; and an epitaxial-growth layer disposed on the substrate, wherein a surface of the epitaxial-growth layer has a {100} or {110} plane.

Specific particulars of other embodiments are included in detailed descriptions and drawings.

### BRIEF DESCRIPTION OF THE DRAWINGS

The foregoing and other features and advantages of the inventive concepts will be apparent from the more-particular description of particular embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIGS. 1A through 1F are conceptual diagrams of semiconductor wafers according to various embodiments of the inventive concept;

FIGS. 2A through 2F are schematic longitudinal sectional views of semiconductor devices according to embodiments of the inventive concept;

FIG. 3 is a flowchart illustrating a method of fabricating a semiconductor device according to an embodiment of the inventive concept;

FIGS. 4A through 4H, 5, 6A, 6B, 7A through 7C, and 8 are longitudinal sectional views illustrating methods of fabricating semiconductor devices according to various embodiments of the inventive concept;

FIG. 9A is a schematic layout of a semiconductor device according to an embodiment of the inventive concept;

FIG. 9B is a schematic longitudinal sectional view taken along line I-I′ of FIG. 9A;

FIG. 10A is a schematic layout of a semiconductor device according to an embodiment of the inventive concept;

FIG. 10B is a schematic longitudinal sectional view taken along line II-II′ of FIG. 10A;

FIG. 11A is a schematic block diagram of a camera system according to an embodiment of the inventive concept;

FIG. 11B is a schematic block diagram of an electronic system according to an embodiment of the inventive concept; and

FIG. 11C is a schematic diagram of a mobile device including at least one semiconductor device according to various embodiments of the inventive concept.

### DETAILED DESCRIPTION OF THE EMBODIMENTS

Example embodiments of the present invention are described below in sufficient detail to enable those of ordinary skill in the art to embody and practice the present invention. It is important to understand that the present invention may be embodied in many alternate forms and should not be construed as limited to the example embodiments set forth herein.

The terminology used herein to describe embodiments of the invention is not intended to limit the scope of the invention. The articles, “a,” “an,” and “the,” are singular in that they have a single referent; however, the use of the singular form in the present document is not to be interpreted as precluding the presence of more than one referent. In other words, elements of the inventive concept referred to in the singular may number one or more, unless the context clearly indicates otherwise. It will be further understood that the terms, “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof. As used herein, the term, “and/or,” includes any and all combinations of one or more of the associated listed items.

Spatially relative terms, such as “below”, “beneath”, “lower”, “above”, “upper”, “lower” and the like, may be used herein for ease of description to describe the relationship of one element or feature to another element(s) or feature(s), as illustrated in the figures. It will be understood that the spatially relative terms are intended to encompass different orientations of the device in use or operation in addition to the orientation depicted in the figures. For example, if the device in the figures is turned over, elements described as “lower” relative to other elements or features would then be oriented “upper” relative to the other elements or features. Thus, the exemplary term, “lower,” can encompass both an orientation of lower and upper. The device may be otherwise oriented (e.g., rotated 90 degrees or at other orientations) and the spatially relative descriptors used herein interpreted accordingly.

Embodiments of the inventive concept are described herein with reference to schematic plan and cross-section illustrations of idealized embodiments of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. For example, a region illustrated as a rectangle will, typically, have rounded or curved features. Thus, the regions illustrated in the figures are schematic in nature and their shapes are not intended to illustrate the precise shape of a region of a device and are not intended to limit the scope of the inventive concept.

Like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

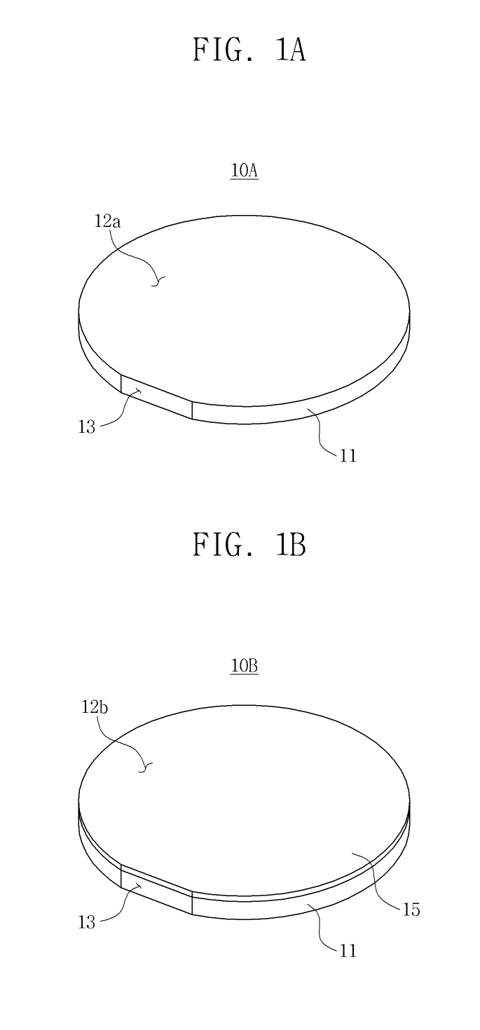

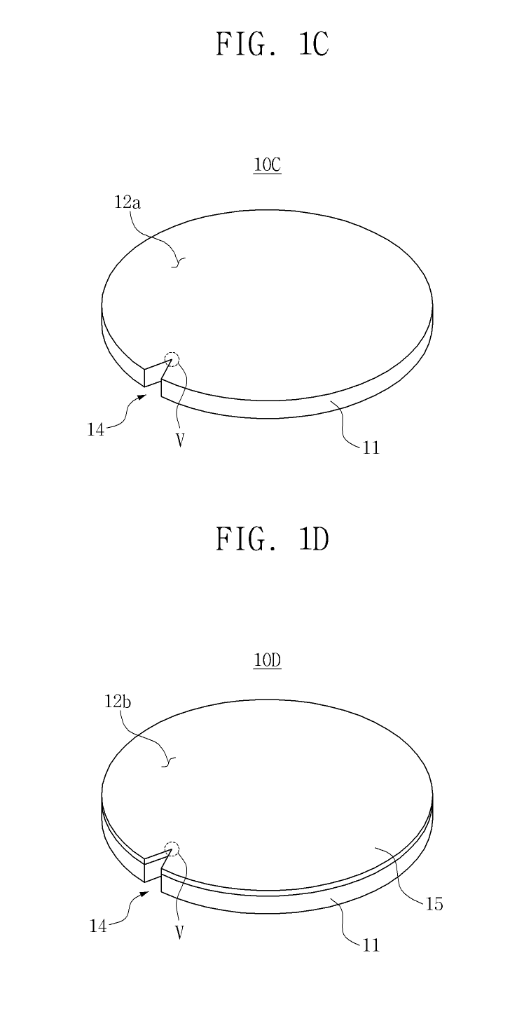

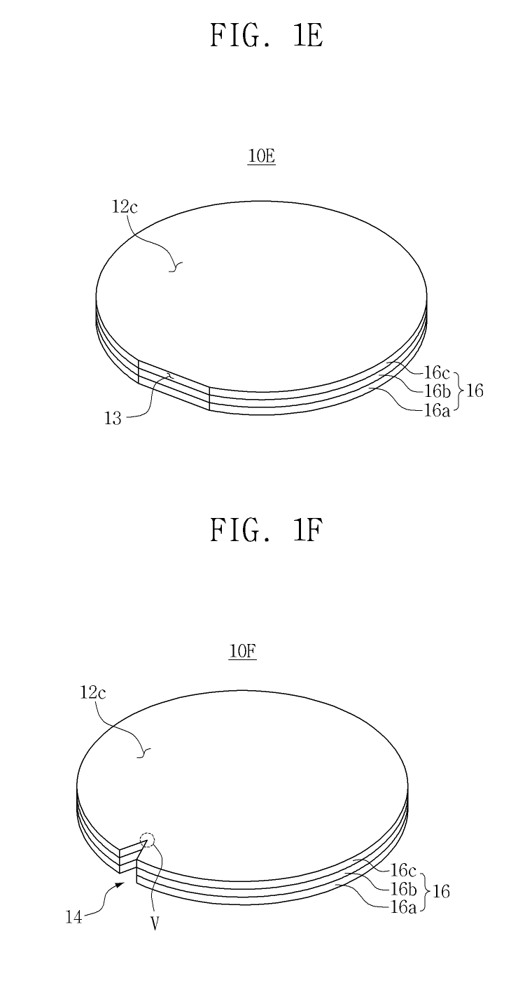

FIGS. 1A through 1F are conceptual diagrams of semiconductor wafers 10A to 10D according to various embodiments of the inventive concept.

Referring to FIG. 1A, the semiconductor wafer 10A, according to an embodiment of the inventive concept, may include a bulk 11 having a surface 12a and a flat zone 13. The surface 12a of the bulk 11 may have a {100} or {110} plane. The flat zone 13 may have a {310}, {311}, {100}, or {110} plane. For example, when the surface 12a of the bulk 11 has a {100} plane, the flat zone 13 may have a {310} or {100} plane. When the surface 12a of the bulk 11 has a {110} plane, the flat zone 13 may have a {311} or {110} plane.

Referring to FIG. 1B, the semiconductor wafer 10B, according to an embodiment of the inventive concept, may likewise include a bulk 11 having a flat zone 13 and may also include an epitaxial-growth layer 15 disposed on the bulk 11. A surface 12b of the epitaxial-growth layer 15 may have a {100} or {110} plane. As in the embodiment of FIG. 1A, the flat zone 13 may have a {310}, {311}, {100}, or {110} plane. For example, when the surface 12b of the epitaxial-growth layer 15 has a {100} plane, the flat zone 13 may have a {310} or {100} plane. When the surface 12b of the epitaxial-growth layer 15 has a {110} plane, the flat zone 13 may have a {311} or {110} plane.

Referring to FIG. 1C, the semiconductor wafer 10C, according to an embodiment of the inventive concept, may include a bulk 11 having a surface 12a and a notch 14. The surface 12a of the bulk 11 may have a {100} or {110} plane. A vertex, V, of the notch 14 may be oriented toward a <310>, <311>, <100>, or <110> orientation. For example, when the surface 12a of the bulk 11 has a {100} plane, the vertex, V, of the notch 14 may be oriented toward a <310> or <100> orientation. When the surface 12a of the bulk 110 has a {110} plane, the vertex, V, of the notch 14 may be oriented toward a <311> or <110> orientation.

Referring to FIG. 1D, the semiconductor wafer 10D, according to an embodiment of the inventive concept, may likewise include a bulk 11 having a notch 14 and may also include an epitaxial-growth layer 15 disposed on the bulk 11. A surface 12b of the epitaxial-growth layer 15 may have a {100} or {110} plane. As in the embodiment of FIG. 1C, a vertex, V, of the notch 14 may be oriented toward a <310>, <311>, <100>, or <110> orientation. For example, when the surface 12b of the epitaxial-growth layer 15 has a {100} plane, the vertex, V, of the notch 14 may be oriented toward a <310> or <100> orientation. When the surface 12b of the epitaxial-growth layer 15 has a {110} plane, the vertex, V, of the notch 14 may be oriented toward a <311> or <110> orientation.

Referring to FIG. 1E, the semiconductor wafer 10E, according to an embodiment of the inventive concept, may include a silicon-on-insulator (SOI) substrate 16 having a flat zone 13. The SOI substrate 16 may include a lower semiconductor layer 16a, an intermediate insulating layer 16b, and an upper semiconductor layer 16c. For example, the lower semiconductor layer 16a and the upper semiconductor layer 16c may include single crystalline silicon, silicon germanium (SiGe), silicon carbon (SiC), or a compound semiconductor. The intermediate insulating layer 16b may include silicon dioxide. A surface 12c of the upper semiconductor layer 16c may have a {100} or {110} plane. The flat zone 13 may have a {310}, {311}, {100}, or {110} plane. For instance, when the surface 12c of the upper semiconductor layer 16c has a {100} plane, the flat zone 13 may have a {310} or {100} plane. When the surface 12c of the upper semiconductor layer 16c has a {110} plane, the flat zone 13 may have a {311} or {110} plane.

The flat zone 13 may have a {310}, {311}, {100}, or {110} plane. For example, when a surface 12a of a bulk 11 has a {100} plane, the flat zone 13 may have a {310} or {100} plane. When the surface 12a of the bulk 11 has a {110} plane, the flat zone 13 may have a {311} or {110} plane.

Referring to FIG. 1F, the semiconductor wafer 10F, according to an embodiment of the inventive concept, may include a SOI substrate 16 having a notch 14. A vertex, V, of the notch 14 may be oriented toward a <310>, <311>, <100> or <110> orientation. For example, when a surface 12c of an upper semiconductor layer 16c has a {100} plane, the vertex, V, of the notch 14 may be oriented toward a <310> or <100> orientation. When the surface 12c of the upper semiconductor layer 16c has a {110} plane, the vertex, V, of the notch 14 may be oriented toward a <311> or <110> orientation.

Referring back to FIGS. 1A through 1F, each of the semiconductor wafers 10A to 10F may include single-crystalline silicon or a compound semiconductor, such as gallium arsenide (GaAs) or aluminum gallium arsenide (AlGaAs). The notch 14 may face imaginary central points of the semiconductor wafers 10A to 10D. The flat zone 13 may include a side surface of the bulk 11 and/or a side surface of the epitaxial-growth layer 15.

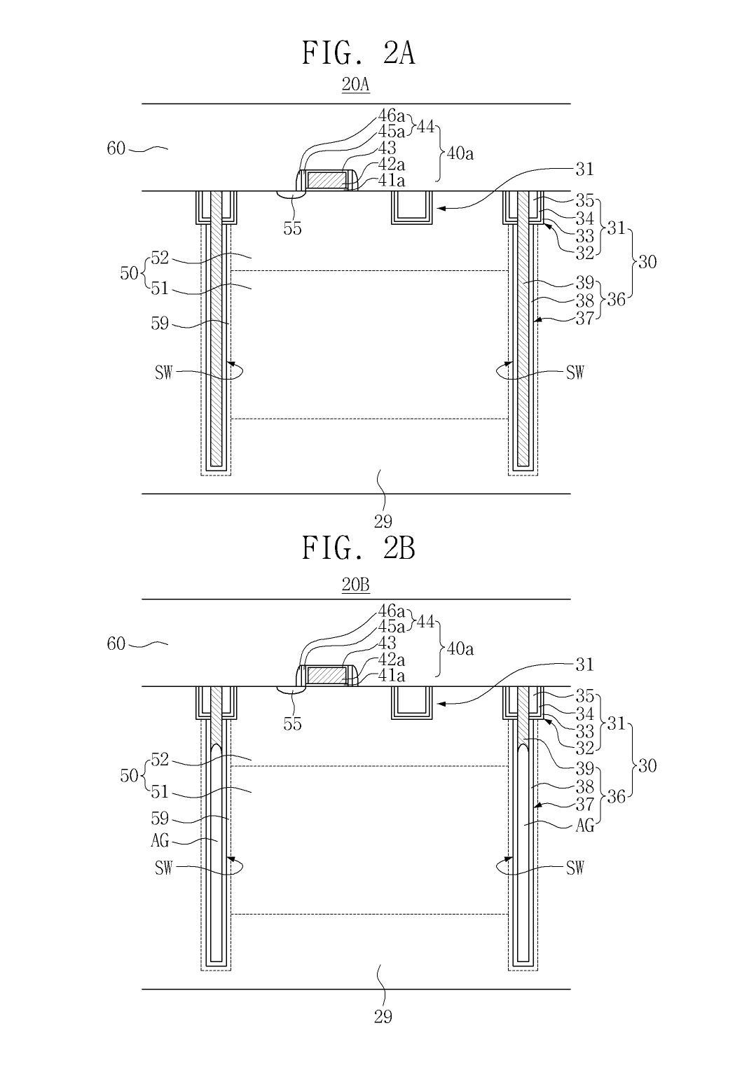

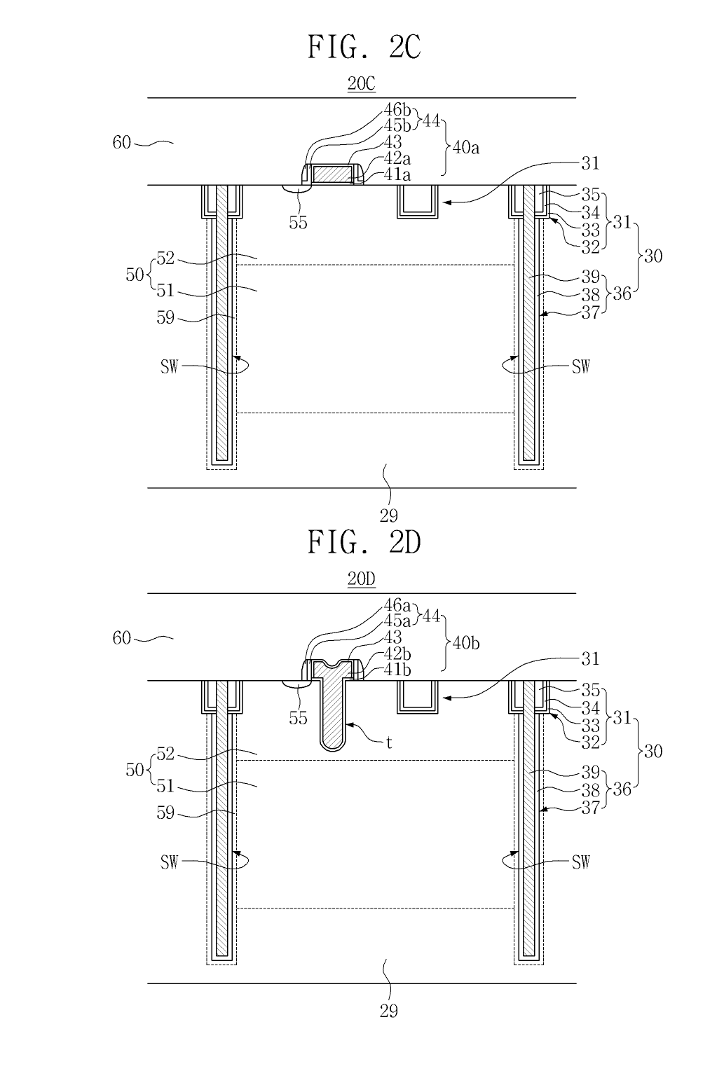

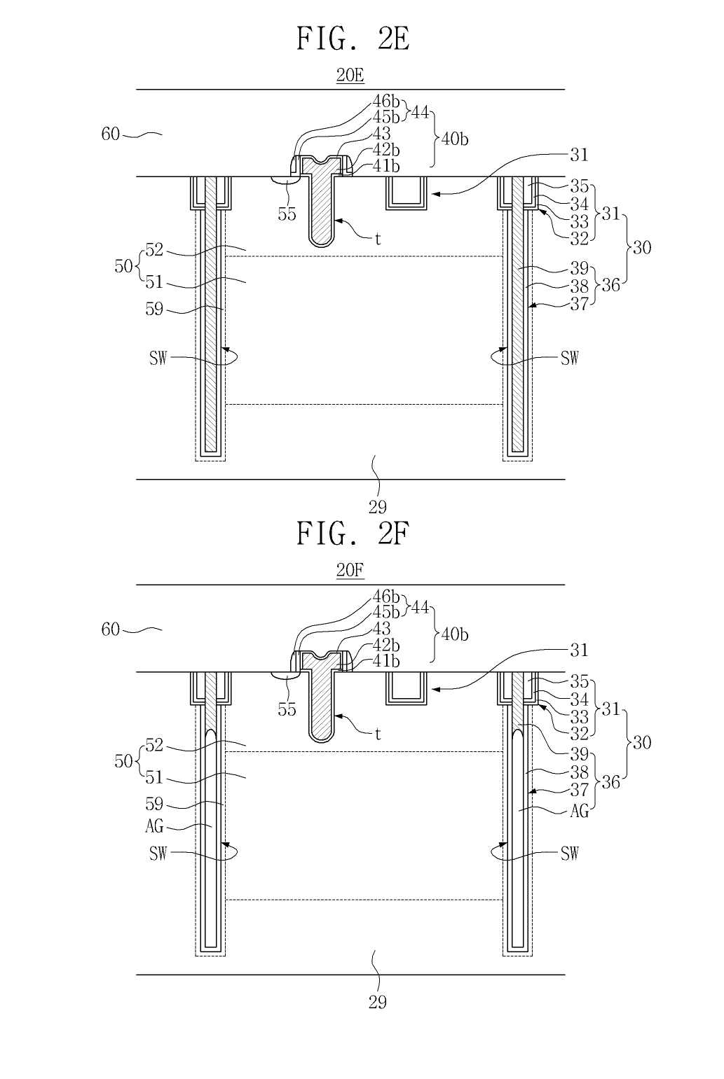

FIGS. 2A through 2F are schematic longitudinal sectional views of semiconductor devices 20A to 20F according to embodiments of the inventive concept. Each of the semiconductor devices 20A to 20F may include an image sensor.

Referring to FIG. 2A, a semiconductor device 20A, according to an embodiment of the inventive concept, may include field regions 30 formed in a device substrate 29 and a planar transistor 40a formed on the device substrate 29. The semiconductor device 20A may further include a photodiode (PD) 50 formed between the field regions 30. The semiconductor device 20A may further include a diffusion region 55 formed between the field region 30 and the planar transistor 40a. The semiconductor device 20A may further include an interlayer insulating layer 60 formed of, for example, silicon dioxide, to cover the planar transistor 40a.

Referring back to FIGS. 1A through 1F, the device substrate 29 may be the bulk 11, the epitaxial-growth layer 15, or the upper semiconductor layer 16c of the semiconductor wafer 10 formed of single-crystalline silicon or a compound semiconductor. Accordingly, a surface of the device substrate 29 may have a {100} or {110} plane.

The field regions 30 may include shallow field regions 31 and deep field regions 36. Each of the shallow field regions 31 may include an outer liner 33, an inner liner 34, and a shallow field-insulating material 35. The outer liner 33 may be conformally formed on an inner wall of the shallow field trench 31 and may include oxidized silicon. For example, the outer liner 33 may be formed by oxidizing the inner wall of the shallow field trench 32. The inner liner 34 may be conformally formed on the outer liner 33 and may include silicon nitride or silicon dioxide. Alternatively, the inner liner 34 may be omitted. The shallow field-insulating material 35 may include silicon dioxide.

Each of the deep field regions 36 may include a deep field liner 38 and a deep field-insulating material 39. The deep field liner 38 may include oxidized silicon. For example, the deep field liner 38 may be formed by oxidizing an inner wall of the deep field trench 37. The deep field-insulating material 39 may include silicon dioxide or undoped polycrystalline silicon (poly-silicon).

The deep field regions 36 and the shallow field regions 31 may be vertically aligned. The deep field-insulating materials 39 may extend between the shallow field-insulating materials 35. For instance, upper portions of the deep field-insulating materials 39 may be surrounded with the shallow field-insulating materials 35 in the shallow field region 31. The shallow field regions 31 may have a greater horizontal width than the deep field regions 36. On the other hand, the deep field regions 36 may have at least twice the depth of the shallow field regions 31. For example, the deep field regions 36 may have about five to six times the depth of the shallow field regions 31.

Side impurity regions 59 may be conformally formed around the deep field regions 36 to surround the deep field regions 36. The side impurity regions 59 may include p-type impurities, such as boron (B), at a dose of about 1E¹²/cm² to 1E¹⁶/cm².

The photodiode 50 may include an n-type impurity region 51 formed in the device substrate 29 and a p-type impurity region 52 formed adjacent to the surface of the device substrate 29. The n-type impurity region 51 may horizontally overlap the deep field regions 36. An upper boundary of the n-type impurity region 51 may be formed to a greater depth than bottom ends of the shallow field regions 31, and a lower boundary of the n-type impurity regions 51 may be formed to a smaller depth than bottom ends of the deep field regions 31. The p-type impurity region 52 may abut the surface of the device substrate 29 and the n-type impurity region 51 and may also abut the side impurity regions 59. Alternatively, the p-type impurity region 52 may abut both the shallow field regions 31 and the deep field regions 36.

At least one of the side surfaces, SW, of the deep field regions 36 may include a {310}, {311}, or {100} plane. Referring back to FIGS. 1A through 1F, at least one of the side surfaces, SW, of the deep field regions 36 may have a crystal plane parallel to a flat zone 13 or orthogonal to a direction in which the vertex, V, of the notch 14 is oriented. The side surfaces, SW, of the deep field regions 36 having a {310}, {311}, or {100} plane may have a lower interface trap density than that of the {110} plane. Accordingly, electrons generated in the photodiode 50 may not be trapped in the side surfaces, SW, of the deep field regions 36 but, instead, may be used to generate and transmit signals very efficiently. The semiconductor device 20A may, therefore, have improved signal-retention efficiency and signal-transmission efficiency. When the semiconductor device 20A is an image sensor, white defects may be reduced, thereby improving resolution of the image sensor.

The planar transistor 40a may include a planar gate-insulating layer 41a, a planar gate electrode 42a, and gate spacers 44. The planar gate-insulating layer 41a may include silicon dioxide. The planar gate electrode 42a may include a conductive material. For example, the planar gate electrode 42a may include poly-silicon containing n-type impurities, such as phosphorus (P) and/or arsenic (As). A surface oxide layer 43 may be thinly formed on the surface of the planar gate electrode 42a. The gate spacers 44 may be formed on side surfaces of the planar gate electrode 42a. The gate spacers 44 may include inner spacers 45a and outer spacers 46a. The inner spacers 45a may include silicon dioxide, while the outer spacers 46a may include silicon nitride.

A diffusion region 55 may be formed in the device substrate 29 such that the diffusion region 55 may be aligned with the gate spacer 44 formed on one side surface of the planar transistor 40a and surrounded with the p-type impurity region 52. The diffusion region 55 may include n-type impurities. Accordingly, the p-type impurity region 52 and the diffusion region 55 may form a p-n junction.

Referring to FIG. 2B, a semiconductor device 20B, according to an embodiment of the inventive concept, may include deep field regions 36 having air gaps, AG. For example, a deep field-insulating material 39 may fill only an upper region of a deep field trench 37 such that an air gap, AG, is formed in a lower region of the deep field trench 37. The deep field-insulating material 39 may extend to fill the inside of a shallow field region 31.

Referring to FIG. 2C, a semiconductor device 20C, according to an embodiment of the inventive concept, may include a planar transistor 40a having inner spacers 45b that extend onto the device substrate 29. The inner spacers 45b may extend onto the surface of the device substrate 29 and be interposed between outer spacers 46b and the surface of the device substrate 29. For example, the inner spacers 45b may have L-shaped longitudinal sections.

Referring to FIG. 2D, a semiconductor device 20D, according to an embodiment of the inventive concept, may include a vertical transistor 40b having a recessed channel. The vertical transistor 40b may include a gate trench, t, extending into a device substrate 29 and a vertical gate electrode 42b. A vertical gate-insulating layer 41b may be conformally formed on an inner wall of the gate trench, t. The vertical gate-insulating layer 41b and the vertical gate electrode 42b may extend onto the surface of the device substrate 29. The vertical transistor 40b may be formed in a p-type impurity region 52. A bottom end of the vertical transistor 40b may be isolated or spaced apart from an n-type impurity region 51.

Referring to FIG. 2E, a semiconductor device 20E, according to an embodiment of the inventive concept, may include a vertical transistor 40b having inner spacers 45b that extend onto a device substrate 29.

Referring to FIG. 2F, a semiconductor device 20F, according to an embodiment of the inventive concept, may include deep field regions 36 having air gaps, AG.

It may be understood that characteristic elements of respective embodiments may be variously compatible and combined with one another with reference to FIGS. 2A through 2F even if they are not illustrated in additional drawings.

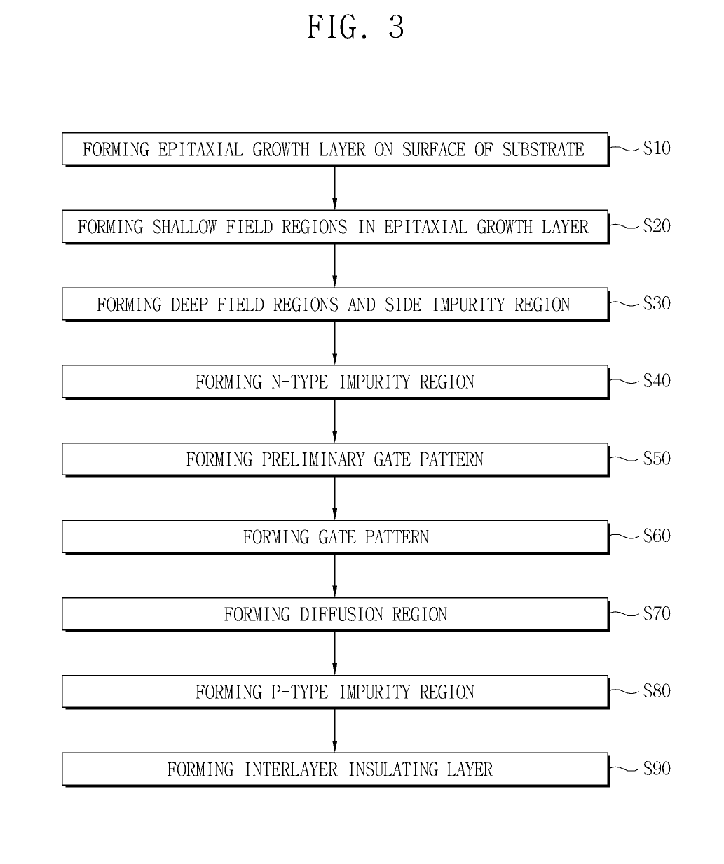

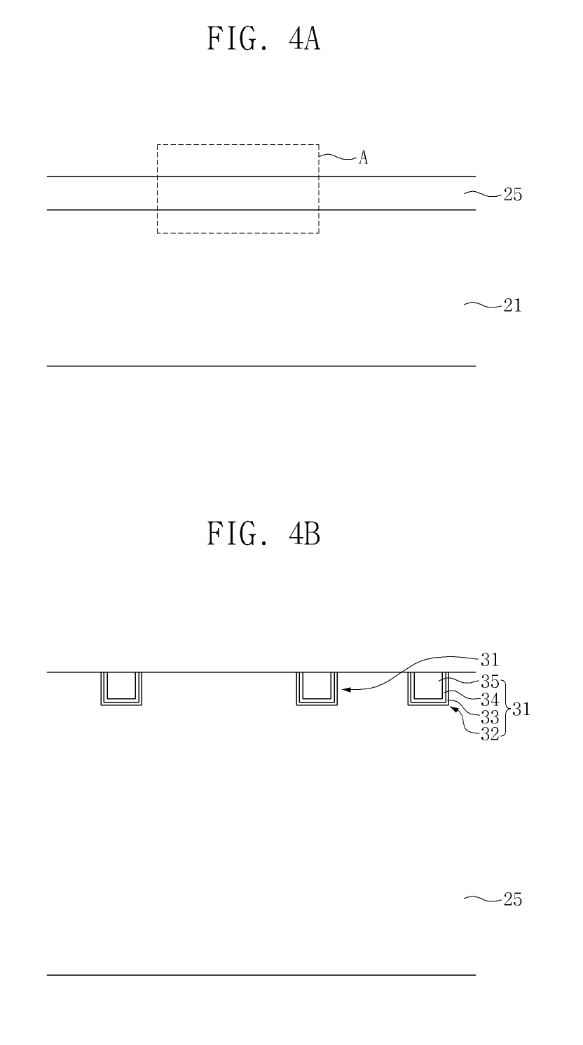

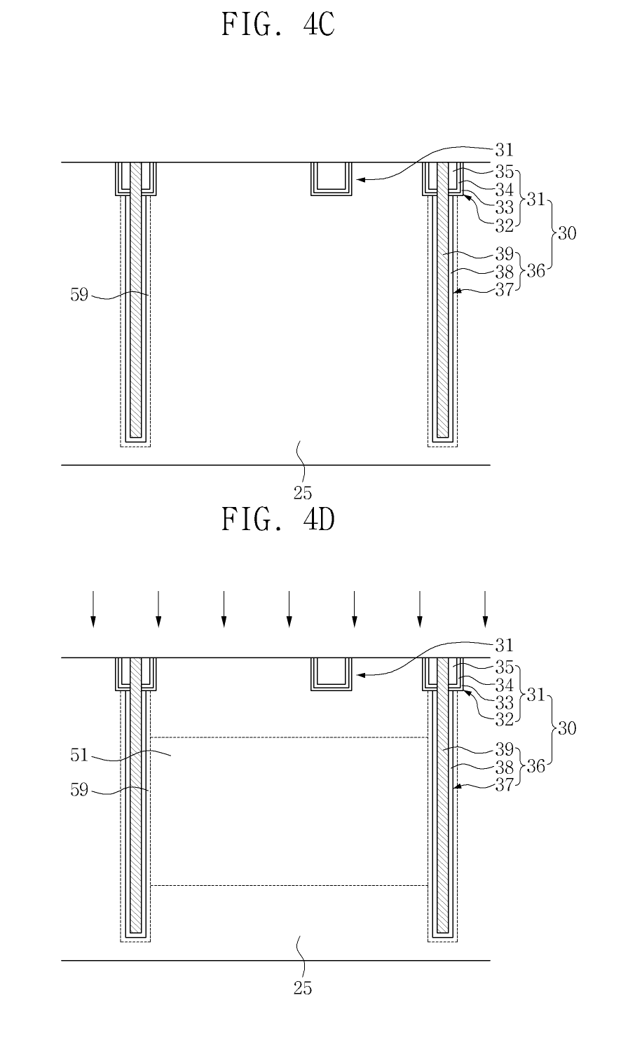

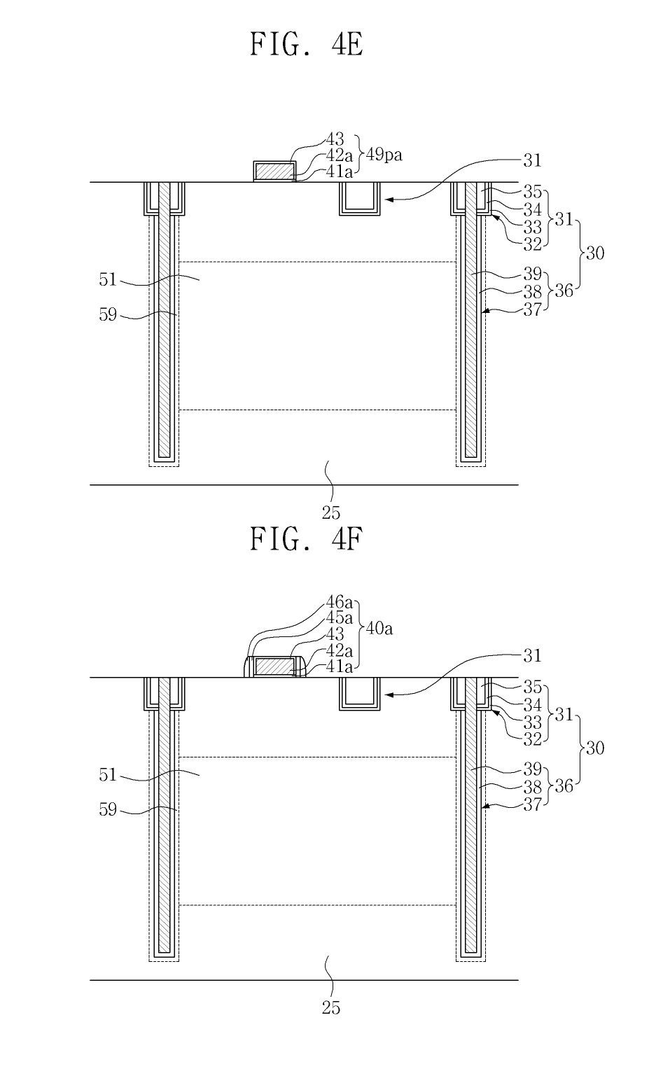

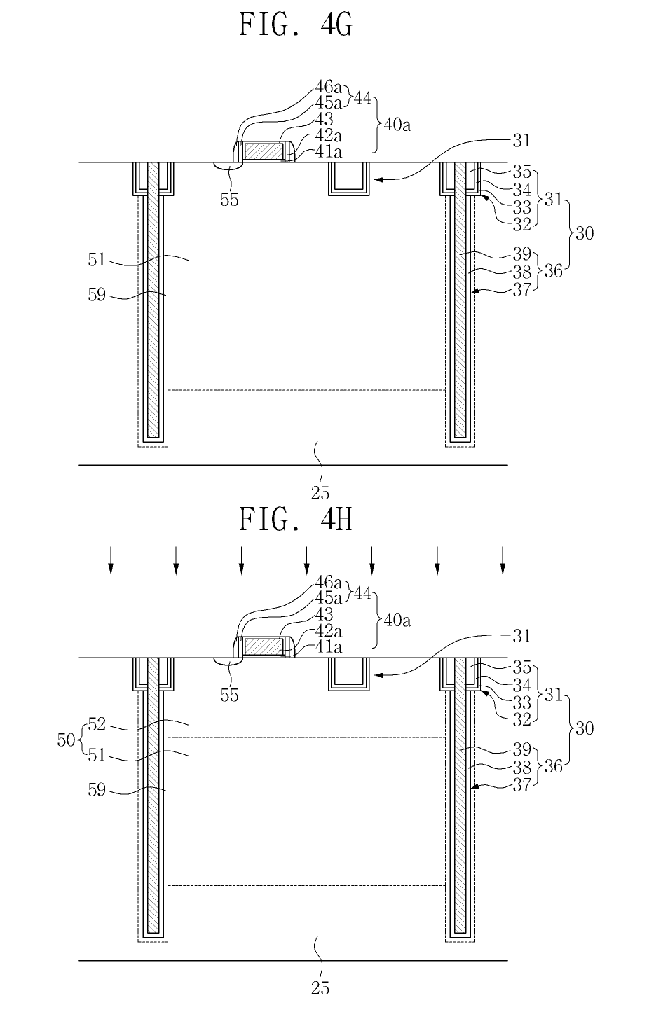

FIG. 3 is a flowchart illustrating a method of fabricating a semiconductor device according to an embodiment of the inventive concept, and FIGS. 4A through 4H are longitudinal sectional views illustrating a method of fabricating a semiconductor device 20A according to an embodiment of the inventive concept.

Referring to FIGS. 3 and 4A, a method of fabricating the semiconductor device 10A, according to an embodiment of the inventive concept, may include forming an epitaxial-growth layer 25 on a surface of a bulk 11 (operation S10). The surface of the bulk 11 may have a {100} plane or a {110} plane. The bulk 11 may be one of the semiconductor wafers 10A to 10D shown in FIGS. 1A through 3D. In the following drawings, a region A illustrated with a dotted line will be enlarged. The process of forming the epitaxial-growth layer 25 will be omitted. Thus, the surface of the epitaxial-growth layer 25 can now be interpreted as being, e.g., any of the surfaces 12a to 12c described with reference to FIGS. 1A through 1F. In addition, the epitaxial-growth layer 25 may be interpreted as being, e.g., one of the device substrates 29 of FIGS. 2A through 2F.

Referring to FIGS. 3 and 4B, a method of fabricating the semiconductor device 20A, according to this embodiment of the inventive concept, may include forming shallow field regions 31 in the epitaxial-growth layer 25 (operation S20). The formation of the shallow field regions 31 may include forming shallow field trenches 32 in the epitaxial-growth layer 25, forming outer liners 33 by oxidizing inner surfaces of the shallow field trenches 32, forming inner liners 34 on the surfaces of the outer liners 33, and forming a shallow field-insulating material 35 on the inner liners 34 to fill the shallow field trenches 32. The outer liners 33 may be formed by thermally oxidizing the surface of the epitaxial-growth layer 25 exposed within the shallow field trenches 32. Accordingly, the outer liners 33 may include thermally oxidized silicon. The inner liners 34 may be conformally formed on the outer liners 33 using a chemical-vapor-deposition (CVD) process. The inner liners 34 may include a denser material than the outer liners 33, for example, silicon nitride (Si₃N₄). The shallow field-insulating material 35 may include silicon dioxide, such as middle-temperature oxide (MTO). After filling the shallow field trenches 32 with the shallow field-insulating material 35, a planarization process, such as a chemical-mechanical polishing (CMP) process, may be performed on the top surface of the device. After the planarization process is performed, shallow field regions 31 may be formed, and the surface of the epitaxial-growth layer 25 may be exposed between the shallow field regions 31.

Referring to FIGS. 3 and 4C, a method of fabricating the semiconductor device 20A, according to this embodiment of the inventive concept, may include forming deep field regions 36 and side impurity regions 59 (operation S30). The deep field regions 36 may vertically overlap or be aligned with the shallow field regions 31. The deep field regions 36 may have a smaller horizontal width than the shallow field regions 31. The formation of the deep field regions 36 may include forming deep field trenches 37 in alignment with portions of the shallow field regions 31, and forming deep field liners 38 by oxidizing the surface of the epitaxial-growth layer 25 exposed within the deep field trenches 37. Afterwards, the method may further include forming a deep field-insulating material 39 on the deep field liners 38 to fill the deep field trenches 37. The deep field-insulating material 39 may include an oxide or poly-silicon.

The side impurity regions 59 may be formed to surround the deep field trenches 37. The formation of the side impurity regions 59 may include forming the deep field regions 36 and performing an ion-implantation process. Alternatively, the formation of the side impurity regions 59 may include forming the deep field trenches 37 and implanting p-type ions, such as boron (B), using a plasma-diffusion process. For instance, the side impurity regions 59 may have an ion dose of about 1E¹²/cm² to 1E¹⁶/cm².

Inner walls of the deep field trenches 37 may be parallel to the flat zone 13 or orthogonal to a vertex, V, of a notch 14. For example, the inner walls of the deep field trenches 37 may have a {310}, {311}, or {100} plane with reference to FIGS. 1A through 1F.

Referring to FIGS. 3 and 4D, a method of fabricating the semiconductor device 10A, according to this embodiment of the inventive concept, may include forming an n-type impurity region 51 (operation S40). The formation of the n-type impurity region 51 may include implanting n-type impurities, such as phosphorus (P) or arsenic (As), into the epitaxial-growth layer 25 using an ion-implantation process. The n-type impurity region 51 may define an n-type region of a photodiode 50. The n-type side impurity region 59 may, for example, have an ion dose of about 1E¹²/cm² to about 1E¹⁶/cm² and may be defined between the deep field regions 36. In other embodiments, when the epitaxial-growth layer 25 originally contains n-type impurities, the process of forming the n-type impurity region 51 may be omitted. For example, before the semiconductor wafers 10A to 10F, shown in FIGS. 1A through 1F, are used in semiconductor fabrication processes, the semiconductor wafers 10A to 10F may be fabricated to contain n-type impurities.

Referring to FIGS. 3 and 4E, a method of fabricating the semiconductor device 10A, according to this embodiment of the inventive concept, may include forming a preliminary planar gate pattern 49pa (operation S50). The formation of the preliminary planar gate pattern 49pa may include forming a gate-insulating-material layer on the surface of the epitaxial-growth layer 25, forming a gate-electrode-material layer on the gate-insulating-material layer, and patterning the gate-electrode-material layer and the gate-insulating-material layer to form a planar gate-insulating layer 41a and a planar gate electrode 42a. The formation of the gate-insulating-material layer may include thermally oxidizing the surface of the epitaxial-growth layer 25. The formation of the gate-electrode-material layer may include forming a conductive-material layer, such as a poly-silicon layer, on the gate-insulating-material layer. The method may further include oxidizing a surface of the patterned planar gate electrode 42a. For example, the method may further include thermally oxidizing the surface of the planar gate electrode 42a to form a surface oxide layer 43 having a small thickness.

Referring to FIGS. 3 and 4F, a method of fabricating the semiconductor device 10A, according to this embodiment of the inventive concept, may include forming a planar gate pattern 40a (operation S60). The formation of the planar gate pattern 40a may include forming gate spacers 44 on side surfaces of the preliminary planar gate pattern 49pa. The gate spacers 44 may include inner spacers 45a and outer spacers 46a. The formation of the inner spacers 45a may include forming an inner spacer-material layer to conformally cover the preliminary planar gate pattern 49pa, and etching back the inner spacer-material layer. The formation of the outer spacers 46a may include forming an outer spacer-material layer on side surfaces of the inner spacers 45a, and etching back the outer spacer-material layer. The inner spacers 45a may include silicon dioxide, such as MTO, which may be formed at a temperature of about 200° C. to about 800° C. The outer spacers 46a may include silicon nitride. An oxidized surface of the planar gate electrode 42a (i.e., the surface oxide layer 43) may be exposed over the planar gate pattern 40a.

Referring to FIGS. 3 and 4G, a method of fabricating the semiconductor device 20A, according to this embodiment of the inventive concept, may include forming a diffusion region 55 (operation S70). The formation of the diffusion region 55 may include implanting n-type impurities, such as phosphorus (P) and/or arsenic (As), into the surface of the epitaxial-growth layer 25 using an ion-implantation process or a plasma-diffusion process. The diffusion region 55 may, for example, have an ion dose of about 1E¹⁴/cm² to about 1E¹⁶/cm².

Referring to FIGS. 3 and 4H, a method of fabricating the semiconductor device 20A, according to this embodiment of the inventive concept, may include forming a p-type impurity region 52 (operation S80). The formation of the p-type impurity region 52 may include implanting boron (B) into an upper region of the n-type impurity region 51 of the epitaxial-growth layer 25 using an ion-implantation process. For example, the p-type impurity region 52 may have an ion dose of 1E12/cm³ to about 1E15/cm³. The n-type impurity region 51 and the p-type impurity region 52 may form a photodiode 50.

Afterwards, referring to FIGS. 3 and 2A, a method of fabricating the semiconductor device 20A, according to this embodiment of the inventive concept, may include forming an interlayer insulating layer 60 to cover the planar gate pattern 40a (operation S90). The formation of the interlayer insulating layer 60 may include forming silicon dioxide using a CVD process.

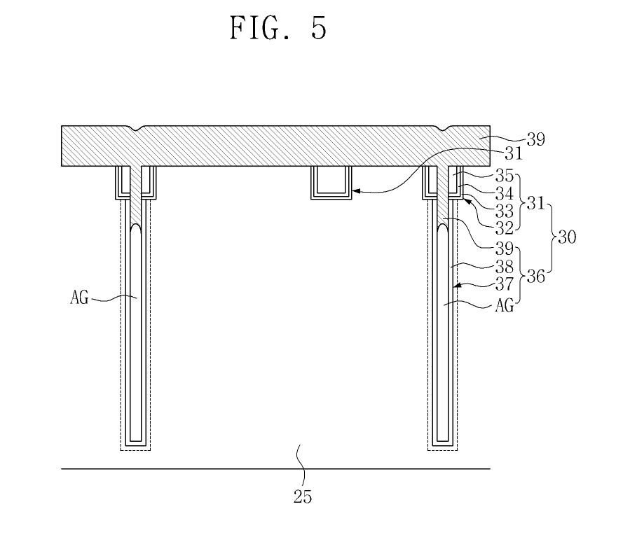

FIG. 5 is a longitudinal sectional view illustrating a method of fabricating a semiconductor device 20B according to an embodiment of the inventive concept. Referring to FIG. 5, a method of fabricating the semiconductor device 20B, according to this embodiment of the inventive concept, may include filling the inside of a shallow field trench 32 and an upper region of a deep field trench 37 with a deep field-insulating material 39, and forming an air gap, AG, in a lower region of the deep field trench 37 during the processes described with reference to FIG. 4C. After forming the deep field-insulating material 39, a planarization process, such as a CMP process, may be performed to remove the deep field-insulating material 39 formed on a surface of an epitaxial-growth layer 25. Subsequently, the method may further include performing the processes described with reference to FIGS. 4D through 4H, and forming an interlayer insulating layer 60 with processes described with further reference to FIG. 1B.

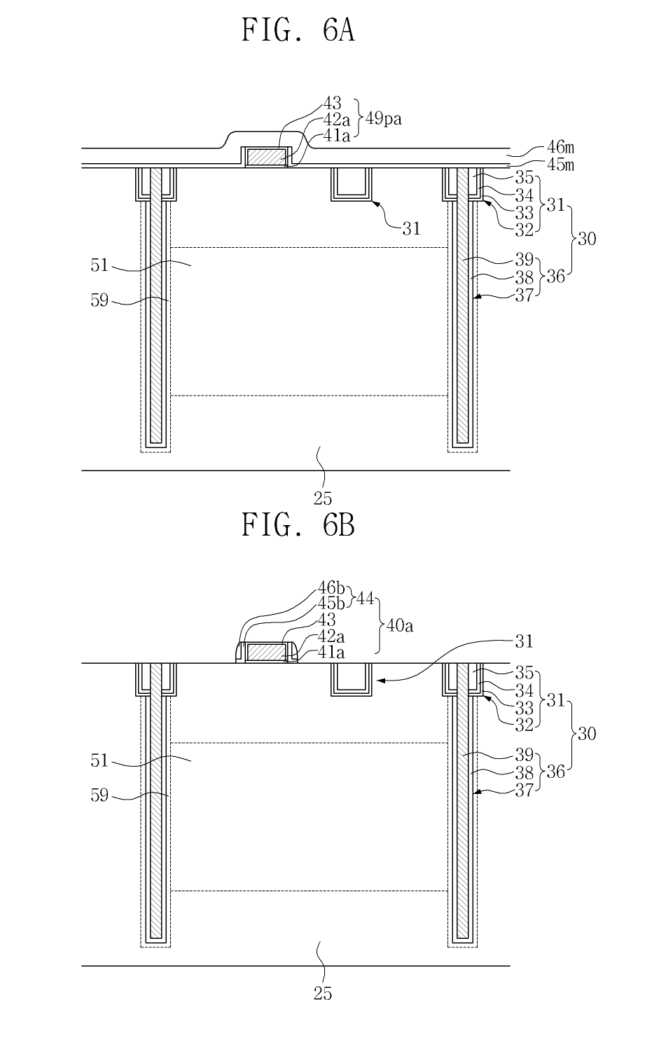

FIGS. 6A and 6B are longitudinal sectional views illustrating a method of fabricating a semiconductor device 20C according to an embodiment of the inventive concept.

Referring to FIG. 6A, a method of fabricating the semiconductor device 20C, according to this embodiment of the inventive concept, may include forming an inner spacer-material layer 45m and an outer spacer-material layer 46m on side surfaces of the preliminary planar gate pattern 49pa and on a portion of a surface of the epitaxial-growth layer 25. Referring back to FIG. 4F, the inner spacer-material layer 45m may include silicon dioxide, while the outer spacer-material layer 46m may include silicon nitride.

Referring to FIG. 6B, a method of fabricating the semiconductor device 20C according to this embodiment of the inventive concept may include forming gate spacers 44. The formation of the gate spacers 44 may include etching back the outer spacer-material layer 46m and the inner spacer-material layer 45m. Subsequently, the method may include performing the processes described with reference to FIGS. 4G and 4H and forming an interlayer insulating layer 60, as described with further reference to FIG. 2C.

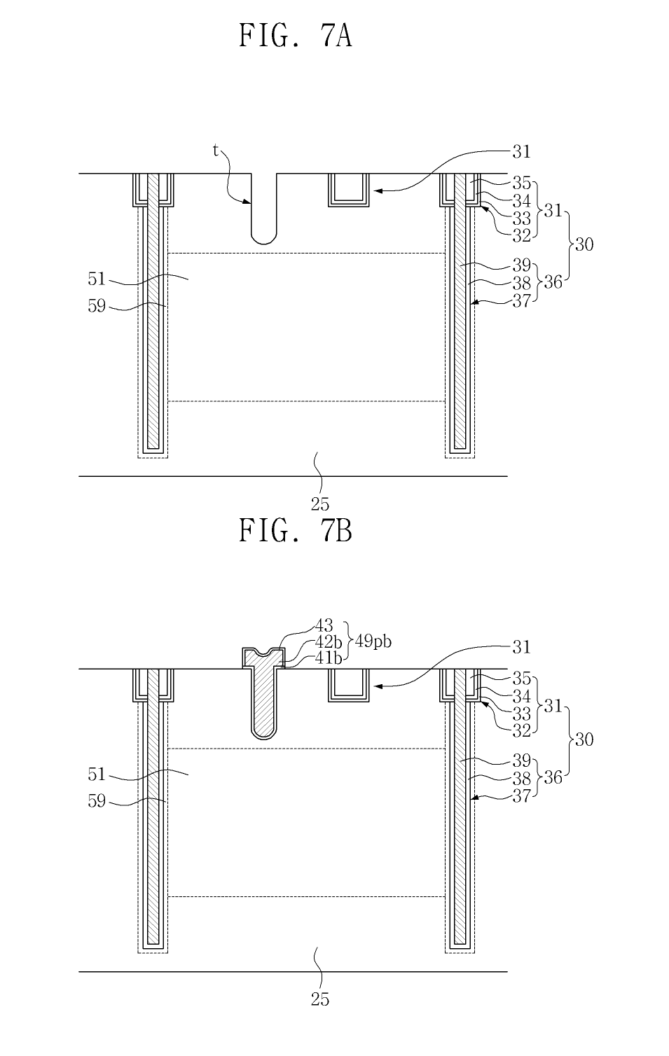

FIGS. 7A through 7C are longitudinal sectional views illustrating a method of fabricating a semiconductor device 20D according to an embodiment of the inventive concept.

Referring to FIG. 7A, a method of fabricating the semiconductor device 20D according to this embodiment of the inventive concept may include forming a gate trench, t, after the processes described with reference to FIGS. 4A through 4D. A gate trench, t, may be spaced apart from an n-type impurity region 51.

Referring to FIG. 7B, a method of fabricating the semiconductor device 20D according to this embodiment of the inventive concept may include forming a gate-insulating-material layer on an inner wall of the gate trench, t; forming a gate-electrode-material layer on the gate-insulating-material layer to fill the gate trench, t, and patterning the gate-electrode-material layer and the gate-insulating-material layer to form a preliminary vertical gate pattern 49pb, including a vertical gate-insulating layer 41b and a vertical gate electrode 42b. Subsequently, the surface of the vertical gate electrode 42b may be thinly oxidized to form a surface oxide layer 43.

Referring to FIG. 7C, a method of fabricating a semiconductor device 20D, according to an embodiment of the inventive concept, may include forming gate spacers 44 on side surfaces of a preliminary vertical gate pattern 49pb to form a vertical gate pattern 40b. The formation of the gate spacers 44 may be understood with reference to the processes described with reference to FIG. 4F. Subsequently, the method may further include performing the processes described with reference to FIGS. 4G and 4H and forming an interlayer insulating layer 60, as described with further reference to FIG. 2D.

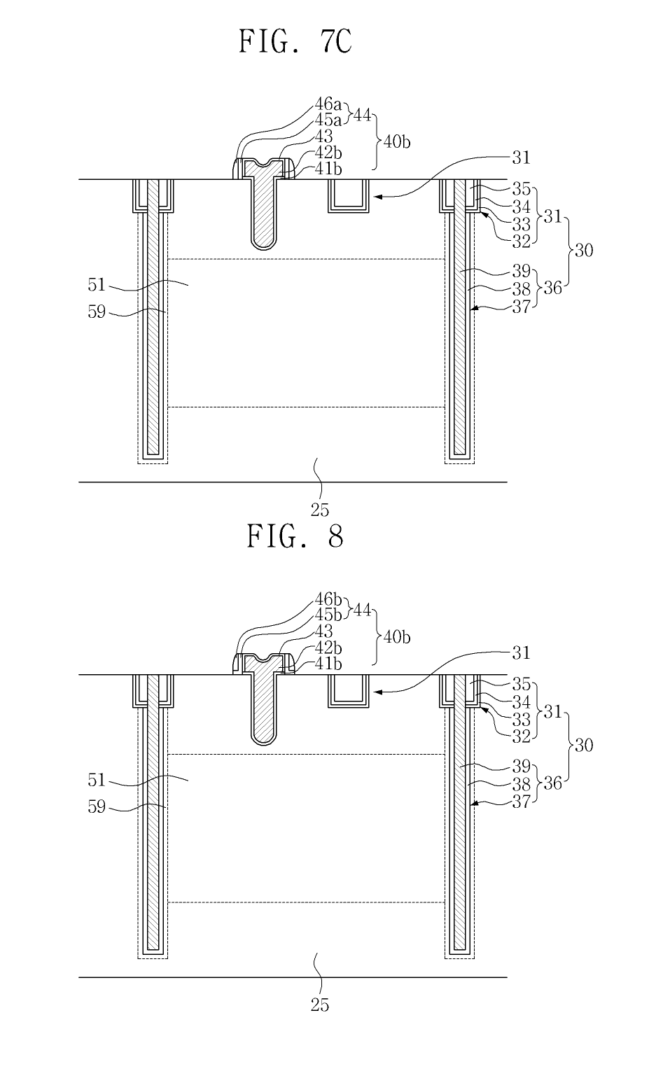

FIG. 8 is a longitudinal sectional view illustrating a method of fabricating a semiconductor device 20E according to an embodiment of the inventive concept. Referring to FIG. 8, a method of fabricating the semiconductor device 20E, according to this embodiment of the inventive concept, may include performing the processes described with reference to FIGS. 6A and 6B to form a gate pattern 40b having inner spacers 45b extending onto the surface of an epitaxial-growth layer 25 after the processes described with reference to FIG. 7B. Afterwards, the method may include forming an interlayer insulating layer 60 with further reference to FIG. 2E.

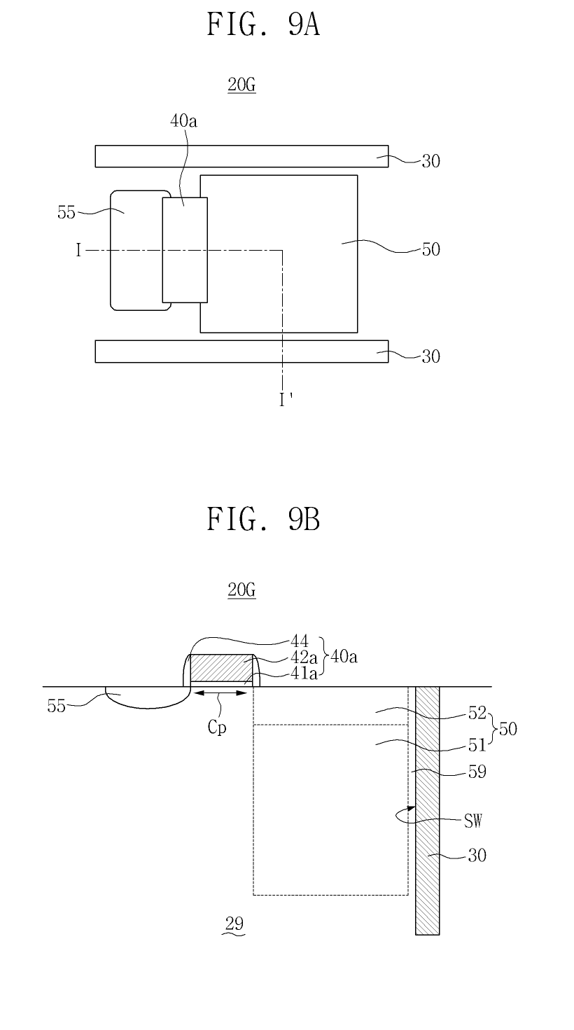

FIG. 9A is a schematic layout of a semiconductor device 20G according to an embodiment of the inventive concept, and FIG. 9B is a longitudinal sectional view taken along line of FIG. 9A.

Referring to FIGS. 9A and 9B, a semiconductor device 20G, according to this embodiment of the inventive concept, may include field regions 30, a photodiode 50, and a diffusion region 55, each of which may be formed in a device substrate 29, and a planar transistor 40a formed on the device substrate 29. The field regions 30 may be disposed in at least two directions of the photodiode 50. The photodiode 50 may include an n-type impurity region 51 formed in a deep position of the device substrate 29, and a p-type impurity region 52 configured to abut a surface of the device substrate 29. The field regions 30 may extend to a greater depth than a bottom end of the n-type impurity region 51. A p-type side impurity region 59 may be formed between the field region 30 and the n-type impurity region 51. The planar transistor 40a may be disposed on the device substrate 29. The planar transistor 40a may include a planar gate-insulating layer 41a, a planar gate electrode 42a, and gate spacers 44. The planar transistor 40a may partially overlap the photodiode 50. The diffusion region 55 may be disposed in the device substrate 29 to face the photodiode 50 across the planar transistor 40a and may include n-type impurities. A side surface, SW, of the field region 30 may be orthogonal to the lengthwise direction of a channel, Cp, of the planar transistor 40a.

The device substrate 29 may be one of the semiconductor wafers 10A to 10F shown in FIGS. 1A through 1F. Thus, the surface of the device substrate 29 may have a {100} or {110} plane. The side surface, SW, of the field region 30 may be parallel to a flat zone 13 or orthogonal to a direction in which a vertex, V, of a notch 14 is oriented. Specifically, the side surface, SW, of the field region 30 may be one of a {100}, {110}, {310}, or {311} plane. For example, the surface of the device substrate 29 may have a {100} or {110} plane, the side surface, SW, of the field region 30 may have a {100}, {110}, {310}, or {311} plane, and the channel, Cp, of the planar transistor 40a may be oriented in a <100>, <110>, <310>, or <311> orientation. Alternatively, the surface of the device substrate 29 may have a {100} or {110} plane; the side surface, SW, of the field region 30 may have a {100}, {310}, or {311} plane; and the channel, Cp, of the planar transistor 40a may be oriented in a <100>, <110>, <310>, or <311> orientation.

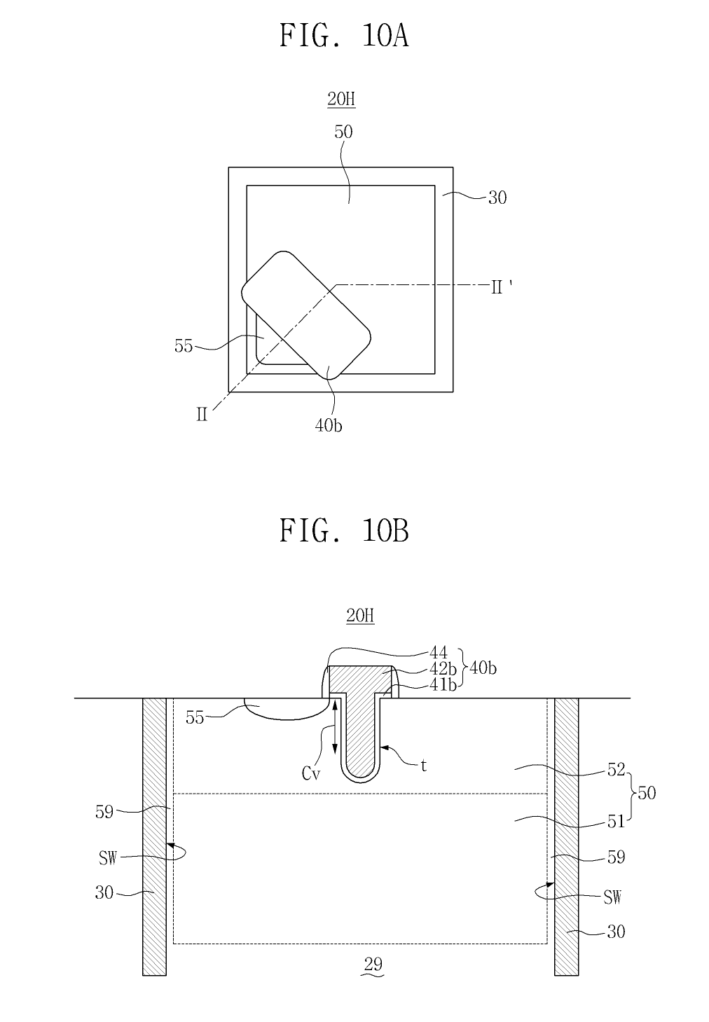

FIG. 10A is a schematic layout of a semiconductor device 20H according to an embodiment of the inventive concept, and FIG. 10B is a longitudinal sectional view taken along line II-II′ of FIG. 10A.

Referring to FIGS. 10A and 10B, a semiconductor device 20H according to this embodiment of the inventive concept may include field regions 30, a photodiode 50, a diffusion region 55, and a vertical transistor 40b. The field regions 30 may be disposed to surround at least two to four sides of the photodiode 50. A p-type side impurity region 59 may be formed between the field regions 30 and the n-type impurity region 51 of the photodiode 50.

The vertical transistor 40b may include a gate trench, t; a vertical gate-insulating layer 41b conformally formed on an inner wall of the gate trench, t; and a vertical gate electrode 420b and gate spacers 44 filling the gate trench, t. A diffusion region 55 may be disposed in the device substrate 29 and face the photodiode 50 across the vertical transistor 40b. The vertical transistor 40b may include a vertical channel, Cv, extending into the device substrate 29 in a direction orthogonal to the surface of the device substrate 29. The vertical channel, Cv, may have a <100> or <110> orientation.

A width direction of the channel, Cv, of the vertical transistor 40b may form a predetermined angle with side surfaces, SW, of the field regions 30. It is assumed in the drawings that the width direction of the channel, Cv, of the vertical transistor 40b forms an angle of about 45° with the side surfaces SW of the field regions 30. However, the angle formed by the width direction of the channel, Cv, of the vertical transistor 40b with the side surfaces SW of the field regions 30 may be variously set within a range of about 15° to about 75°. For example, the angle may be variously set within a range of about 15° to about 30°. Referring back to FIGS. 1A through 1F, the side surfaces, SW, of the field regions 30 may be parallel to or orthogonal to the flat zone 13. Alternatively, the side surfaces, SW, of the field regions 30 may be parallel to or orthogonal to a direction in which the vertex, V, of the notch 14 is oriented. Accordingly, the side surfaces, SW, of the field regions 30 may be oriented on a {100} plane, a {110} plane, a {310} plane, or a {311} plane. For example, a surface of the device substrate 29 may have a {100} or {110} plane; the side surfaces, SW, of the field regions 30 may have a {100}, {110}, {310}, or {311} plane; and the vertical channel, Cv, of the vertical transistor 40b may have a <100> or <110> orientation.

Elements described with reference to FIGS. 9A through 10B will be understood in further detail with further reference to other appended drawings.

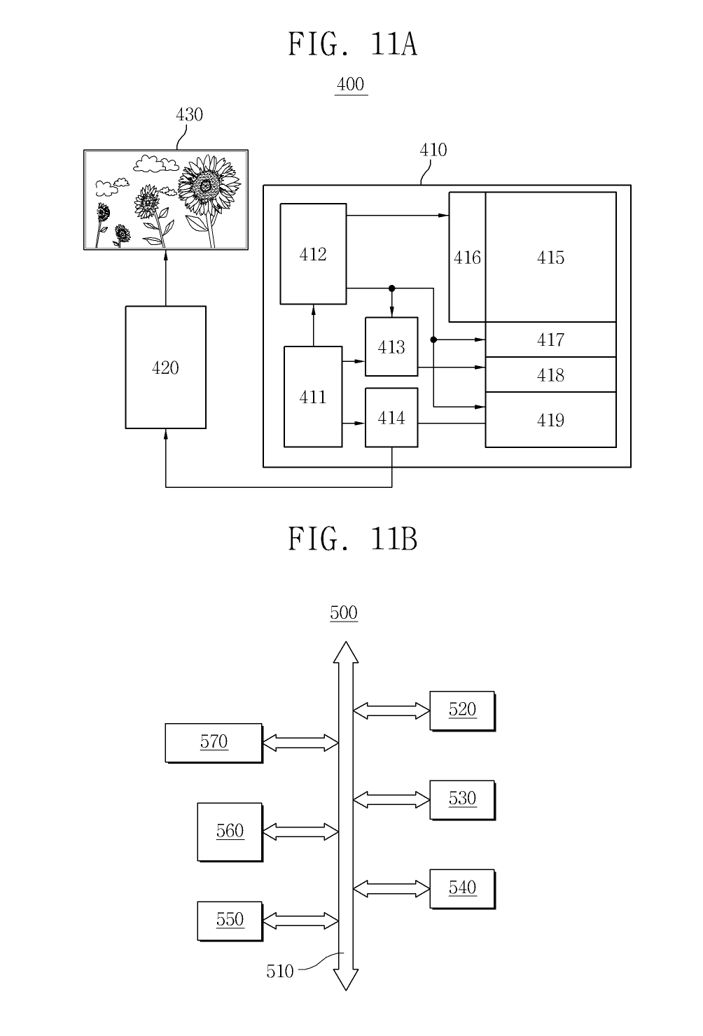

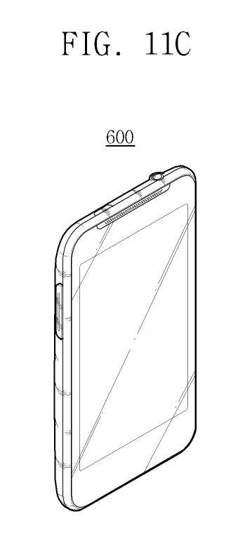

FIG. 11A is a schematic block diagram of a camera system 400 according to an embodiment of the inventive concept. Referring to FIG. 11A, the camera system 400 according to this embodiment of the inventive concept may include an image-sensing part 410, an image-signal-processing part 420, and an image-display part 430. The image-sensing part 410 may include a control register block 411, a timing generator 412, a lamp generator 413, a buffer part 414, an active-pixel sensor array 415, a row driver 416, a correlated double sampler 417, a comparator 418, and an analog-to-digital converter (ADC) 419. The control register block 411 may generally control operations of camera system 400. In particular, the control register block 411 may directly transmit operation signals to the timing generator 412, to the lamp generator 413, and to the buffer part 414. The timing generator 412 may generate a signal serving as a basis for a point in time in which several elements of the image-sensing part 410 operate. An operation-timing-basis signal generated by the timing generator 412 may be transmitted to the row driver 416, to the correlated double sampler 417, to the comparator 418, and/or to the ADC 419. The lamp generator 413 may generate and transmit lamp signals used by the correlated double sampler 417 and/or by the comparator 418. The buffer part 414 may include a latch circuit and may temporarily store an image signal to be externally transmitted. The active-pixel sensor array 415 may sense an external image. The active-pixel sensor array 415 may include a plurality of active-pixel sensors. Each of the active-pixel sensors may include a back-illuminated image sensor according to an embodiment of the inventive concept. The row driver 416 may selectively enable a row of the active-pixel sensor array 415. The correlated double sampler 417 may sample and output an analog signal generated by the active-pixel sensor array 415. The comparator 418 may compare data transmitted by the correlated double sampler 417 with a slope of a lamp signal fed back according to analog reference voltages and may generate various reference signals. The ADC 419 may convert analog image data into digital image data. The image-sensing part 410 may include one of the semiconductor devices 20A to 20H according to embodiments of the inventive concept.

FIG. 11B is a schematic block diagram of an electronic system 500 according to an embodiment of the inventive concept. Referring to FIG. 11B, the electronic system 500 according to this embodiment of the inventive concept may include a bus 510; an image sensing unit 520; a central processing unit (CPU) 530; and an input/output (I/O) part 540, which may transmit and receive data through the bus 510. The electronic system 500 may further include a memory drive 550. The electronic system 500 may further include an optical disk drive (ODD) 560. The electronic system 500 may further include an external communication part 570. The image sensing unit 520 may include a back-illuminated image sensor according to an embodiment of the inventive concept. The CPU 530 may include a microprocessor (MP). The I/O part 540 may include one of various input devices, including an operation button, a switch, a keyboard, a mouse, a keypad, a touch pad, a scanner, a camera, and an optical sensor, or include a liquid-crystal-display (LCD) monitor, a light-emitting-diode (LED) monitor, or cathode-ray tube (CRT) monitor; a printer; and/or another display device configured to display various pieces of visual information. The memory drive 550 may include dynamic random-access memory (DRAM), static RAM (SRAM), phase-change RAM (PRAM), resistive RAM (RRAM), magnetic RAM (MRAM), non-volatile memory (NVM), a flash-memory device, a solid-state disk (SSD), and/or various other memory devices or drives therefor. The optical disk drive 560 may include, for example, a compact-disk read-only memory (CD-ROM) drive or a digital versatile disk (DVD) drive. The external-communication part 570 may include a modem, a local-area-network (LAN) card, or a universal serial bus (USB) and may further include external memory, a wireless-broadband (WiBro) communication device, and an infrared (IR) communication device. The image-sensing unit 520 may include one of the semiconductor devices 20A to 20H according to embodiments of the inventive concept.

FIG. 11C is a schematic diagram of a mobile device 600 including at least one of the semiconductor devices 20A to 20H according to various embodiments of the inventive concept. Referring to FIG. 11C, the mobile device 600 may include a mobile phone or a tablet personal computer (PC). In addition, at least one of the semiconductor devices 20A to 20H according to embodiments of the inventive concept may be used not only for a tablet PC but also for a portable computer such as a laptop computer, an MPEG-1 audio layer 3 (MP3) player, an MP4 player, a navigation device, a solid-state drive (SSD), a desktop computer, or electronic devices for automotive and household uses.

In semiconductor devices and/or image sensors according to various embodiments of the inventive concept, field regions can have few dangling bonds at boundaries thereof. Accordingly, signal-retention capability and signal-transmission efficiency can improve; white-spot defects of the image sensors can be reduced to enhance resolution; and the definition of images can increase.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

What is claimed is:

1. A semiconductor device comprising:
a substrate
field regions formed in the substrate, the field regions having side surfaces; and
n-type impurity regions disposed between the field regions,
wherein at least one of the side surfaces of the field regions has a {100}, {310}, or {311} plane.

2. The device of claim 1, wherein the substrate includes an epitaxial-growth layer.

3. The device of claim 2, wherein a surface of the epitaxial-growth layer has a {100} plane.

4. The device of claim 1, wherein the field regions include a shallow field region and a deep field region, the deep field region extending deeper into the substrate than the shallow field region extends, and a side surface of the deep field region having the {100}, {310}, or {311} plane.

5. The device of claim 4, wherein the shallow field region is vertically aligned with the deep field region and has a greater horizontal width than the deep field region.

6. The device of claim 4, wherein each of the n-type impurity regions horizontally overlaps the deep field region.

7. The device of claim 4, wherein each of the n-type impurity regions has (a) an upper boundary having a depth greater than a depth of a bottom end of the shallow field region and (b) a lower boundary having a depth smaller than a depth of a bottom end of the deep field region.

8. The device of claim 1, further comprising a side impurity region interposed between the field regions and the n-type impurity region,
wherein the side impurity region includes at least one p-type impurity.

9. The device of claim 1, further comprising a p-type impurity region formed in the substrate,
wherein the p-type impurity region is formed between the n-type impurity region and a surface of the substrate.

10. The device of claim 9, further comprising:
a transistor formed on the substrate and configured to overlap with the p-type impurity region; and
a diffusion region formed in the substrate and aligned with a side surface of the transistor.

11. The device of claim 10, wherein the transistor comprises:
a gate trench recessed into the substrate;
a gate insulating layer conformally formed on an inner wall of the gate trench; and
a gate electrode filling the gate trench.

12. The device of claim 10, wherein the transistor includes a vertical channel that is oriented in a <100> or <110> orientation.

13. The device of claim 10, wherein the transistor includes a channel having a width direction that forms an angle of about 15° to about 75° with the side surfaces of the field regions.

14. The device of claim 9, wherein the p-type impurity region abuts the field regions.

15. A semiconductor device comprising:
an epitaxial-growth layer having a surface with a {100} or {110} plane;
at least two field regions formed in the epitaxial-growth layer, each of the field regions having a side surface with a {100}, {110}, {310}, or {311} plane;
a photodiode formed between the field regions, the photodiode including an n-type impurity region formed in the epitaxial-growth layer, and a p-type impurity region configured to abut the surface of the epitaxial-growth layer;
a transistor formed in the p-type impurity region and having a vertical channel oriented in a <100> or <110> orientation; and
a diffusion region formed in the p-type impurity region and aligned with a side surface of the transistor,
wherein the vertical channel of the transistor extends along a lengthwise direction that forms an angle of about 15° to about 75° with the side surface of the field region.

16. The device of claim 15, wherein the field regions include a shallow field region and a deep field region, the deep field region extending deeper into the epitaxial-growth layer than the shallow field region extends.

17. The device of claim 16, wherein a side surface of the deep field region has a {100}, {310}, or {311} plane.

18. The device of claim 15, wherein the p-type impurity region is formed between the n-type impurity region and a surface of the epitaxial-growth layer.

19. The device of claim 18, wherein the n-type impurity region has (a) an upper boundary having a depth greater than a depth of a bottom end of the shallow field region and (b) a lower boundary having a depth smaller than a depth of a bottom end of the deep field region.

20. A semiconductor device, comprising:
a substrate having a side surface at least one of a {310}, {311}, {100}, or {110} plane, the side surface being orthogonal to a top surface of the substrate; and
an epitaxial-growth layer disposed on the substrate, wherein a surface of the epitaxial-growth layer has a {100} or {110} plane.
